(19) United States
(12) Patent Application Publication
(10) Pub. No.: US 2005/0037521 A1
(43) Pub. Date: Feb. 17, 2005

(54) Methods and apparatus for processing semiconductor devices by gas annealing

(76) Inventor: Uwe Wellhausen, Dresden (DE)

Correspondence Address: FISH & RICHARDSON, PC, 12390 EL CAMINO REAL, SAN DIEGO, CA, 92130-2081, US

(21) Appl. No.: 10/641,786

(22) Filed: Aug. 15, 2003

(51) Int. Cl. H01L 21/00; H01L 21/324; H01L 21/477

(52) U.S. Cl. 438/3; 438/795

(57) ABSTRACT

An annealing apparatus comprises a first chamber and a second chamber. A wafer can be located between the chambers, with a first of its surfaces in the first chamber and a second of its surfaces in the second chamber. Different gases are fed to the two chambers, so that, during an annealing step, the components proximate the two chambers are exposed to different gaseous atmospheres. Gas can penetrate from the top and bottom chambers into the wafer, but interdiffusion is blocked by a diffusion blocker layer (e.g. Si₃N₄) within the wafer (e.g. separating CMOS devices from ferrocapacitor devices). If one of the gases is active in a thermal treatment (e.g. a hydrogen-rich gas for performing a CMOS device fabrication step), then the other gas may be inert, so that certain regions of the wafer are not subjected to the treatment step.

### FIELD OF THE INVENTION

The present invention relates to integrated circuit fabrication methods which include at least one step of gas annealing, that is exposing a wafer which is being formed into the integrated circuit to a gaseous environment at an elevated temperature.

### BACKGROUND OF INVENTION

Present integrated circuit fabrication processes often include gas annealing steps. For example, FeRAM devices, i.e. memory devices which include multiple “ferrocapactitors” (layers of ferroelectric material sandwiched between electrode layers), conventionally include CMOS (complimentary metal-oxide-semiconductor) devices, which are formed on the wafer by a process which includes a final step of gas annealing in a hydrogen rich atmosphere.

Although these gas annealing steps are necessary for the production of certain components on the wafer, they may cause damage to other components. For example, during the gas annealing process described above which is used in fabricating FeRAM devices, hydrogen may diffuse through the wafer substrate and the structure formed on it, and cause damage to the ferroelectric material. Measures may be taken to reduce this diffusion, such as the formation of barrier layers (e.g. of Al₂O₃ or TiO₂) above and/or below the ferrocapactitor. However, these measures are often not perfect. For one thing, electrical contacts are necessarily formed to the electrodes of the ferrocapacitors, piercing the barrier layers and thus creating paths by which the hydrogen can diffuse through them. Once hydrogen has penetrated into the structure at the same level as the ferroelectric material, it can diffuse horizontally very easily, since the barrier layers mainly prevent vertical diffusion of the hydrogen.

### SUMMARY OF THE INVENTION

The present invention aims to provide new and useful methods of performing gas annealing steps in integrated circuit fabrication, and new apparatus for performing the methods.

In particular, the methods aim to reduce the unwanted penetration into parts of the wafer of molecules from the gas.

In general terms, the invention proposes that during the annealing process, different portions of the wafer are exposed to different chambers having different gaseous atmospheres, so that certain regions of the wafer are not exposed to atmospheres which might damage certain components on the wafer.

For example, a first of the atmospheres may be active in performing a thermal treatment process on components which come into contact with the first atmosphere, while the second atmosphere may have no reaction with the components it comes into contact with.

In a preferred example, the wafer is one which is to be formed into FeRAM devices, and the first atmosphere may be hydrogen rich and used in a thermal process which is part of a CMOS device fabrication process. The CMOS devices are fabricated on or proximate the silicon surface of the wafer substrate with which the first atmosphere comes into contact. The second atmosphere may have a lower content of hydrogen (such as substantially no hydrogen molecules) and may be applied to a surface of the wafer proximate the ferrocapacitors, e.g. the final passivation layer. The two surfaces of the wafer may be its opposite sides.

The wafer itself (e.g. of Si) and many parts of the device (e.g. an SiO₂ matrix) may be permeable for the gases, so there is a risk of interdiffusion (i.e. mixing of the two atmospheres) due to (i) gas paths existing around the outside of the wafer (any sealing provided between the walls of the chamber and the wafer may not be perfect), and (ii) diffusion of the gases through the wafer material itself.

A possible countermeasure to effect (i), in the case that one of the two atmospheres is active and one inert, is to keep one of the chambers which holds inert gas at a slightly higher pressure than the other, so that the only possible leakage of gas is in the direction from the inert gas to the reactive gas (i.e. ensuring that the portions of the wafer exposed to the inert gas are not exposed to the active gas).

A possible countermeasure to effect (ii) is to provide a layer in the wafer which blocks internal diffusion, such as a nitride layer (or a similar layer, such as Al₂O₃) which separates CMOS devices from ferrocapacitor (FeRAM) devices. In this way it is possible to anneal the CMOS and FeRAM devices separately because the annealing gases penetrate the wafer only from one side, and are internally blocked by the nitride layer.

Specifically, a first expression of the invention is an apparatus for performing an annealing step on a wafer comprising integrated circuit elements, the apparatus comprising:
a first chamber,
a second chamber,
a support for holding the wafer at a location in which a first surface of the wafer is exposed in the first chamber and a second surface of the wafer is exposed in the second chamber,
a heater for heating the wafer in the location,
first and second gas delivery systems for respectively delivering first and second different gases into the first and second chambers, and
pressure regulating devices for regulating the pressure in the first chamber to be different from the pressure in the second chamber.

A second expression of the invention is an integrated circuit fabrication method including a step of maintaining a wafer including one or more integrated circuit elements at a temperature of at least 300° C., a first surface of the wafer being exposed to a first gas and a second surface of the wafer being exposed to a second gas.

### BRIEF DESCRIPTION OF THE FIGURES

Preferred features of the invention will now be described, for the sake of illustration only, with reference to the following figures in which:

FIG. 1 is a schematic diagram of a processing apparatus according to the invention;

FIG. 2 is an electron microscope image of a cross-section of a known wafer suitable for use in a method according to the invention; and

FIG. 3 illustrates the diffusion constant and diffusion distance per hour of hydrogen through Silicon and Silicon oxide.

### DETAILED DESCRIPTION OF THE EMBODIMENTS

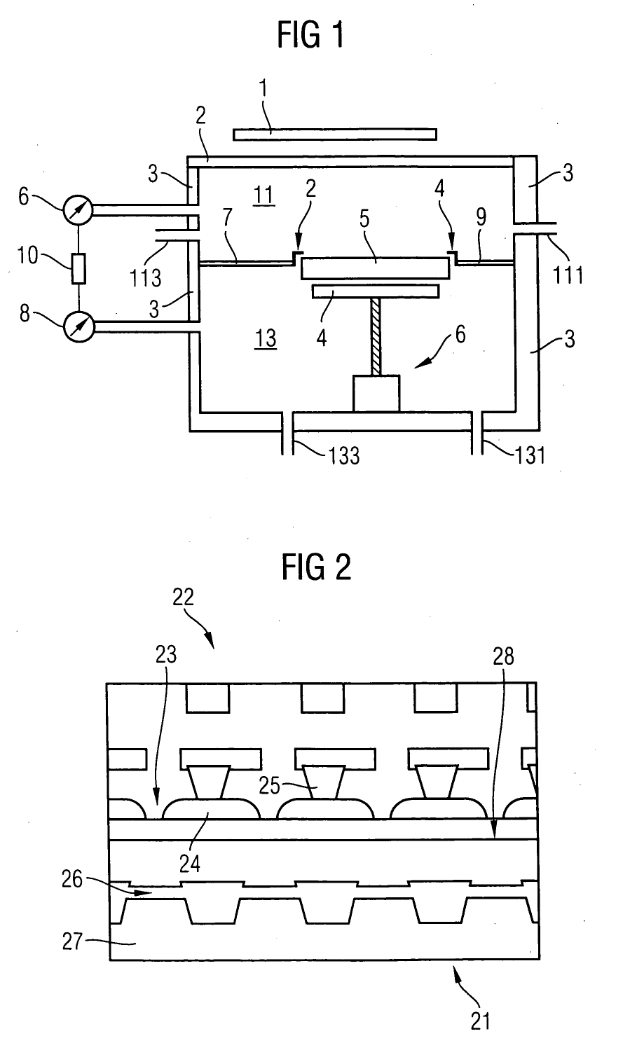

Referring to FIG. 1, a cross section is shown of an annealing apparatus according to the invention. The apparatus is generally hollow, defining a central space, and has a general form resembling a conventional RTP (rapid thermal processing) chamber. For example, the apparatus may include a lamp 1 for generating thermal radiation and one side of the central space may be defined by a quartz window 2 through with the radiation passes. The apparatus may further include insulating elements 3, for maintaining the central space of the apparatus at a selected temperature (typically in the range 300° C. to 900° C.). The apparatus includes a support 4 for holding a wafer 5 which is to be formed into one or more integrated circuit devices. A mechanism 6 is provided for moving the support 4 vertically to a required height. Two partition elements 7, 9 are provided, defining an opening between them slightly larger than the lateral dimensions of the wafer. Optionally, the partition elements 7, 9 include a frame 2, 4 against which the edge of the wafer 5 is slightly pressed (e.g. with a force which is balanced by a higher pressure in the upper chamber, as explained below), thus provided a limited seal to gas pathways around the sides of the wafer 5. When the wafer 5 is located on the support 4, it, together with partition elements 7, 9 partitions the central space in the apparatus into two chambers 11, 13. Each of the chambers 11, 13 is provided with a respective gas inlet 111, 131 and gas outlet 113, 133. The chamber 11 is supplied with a first gas which passes from inlet 111 to outlet 113, while the chamber 13 is supplied with a second, different gas, which passes from inlet 131 to outlet 133.

A differential pressure between the two chambers 11, 13 may be regulated and maintained with high precision, e.g. typically with a tolerance less than 1 mTorr, A tolerance of less than 1 mTorr is suitable for example in the case of an 8″ (21.6 cm) wafer (with increasing wafer diameter the differential pressure may be regulated more precisely, because the larger surface of the water implies increased bending force, even if the pressure difference is constant). This may be done by providing two pressure meters 6, 8 respectively in communication with the chambers 11, 13, and which feed their respective pressure measurement signals to a regulation circuit which controls the supply of the gases to the chambers 11, 13 to ensure that the difference in pressure between the chambers 11, 13 is maintained to a high precision.

For example, suppose that a process is to be applied to the side of the wafer which is exposed to gas in the chamber 13, while no process is to be performed to the side of the wafer 5 which is exposed to the chamber 11, then the first gas may be inert while the second gas is active in the process In this case, the pressure of the inert gas in the chamber 11 is preferably higher than in the chamber 13, so that, even if pathways exist at the sides of the wafer 5 between the chambers 11, 13, there is little risk of the active gas passing from the chamber 13 to the chamber 11. This makes it unnecessary to provide a seal between the sides of the wafer 5 and the partitions 7, 9 (although, optionally, such a seal may be provided in addition).

For example, if the wafer 5 is being formed into FeRAM memory devices, the wafer 5 may be placed with its rear face (i.e. the side of the Si substrate where ferrocapacitor elements are not formed) downwards (in FIG. 1) on the support 4, and thus exposed to the chamber 13, while its upper surface is directed into the chamber 11. The inert gas (which may for example be He, Ar or N₂) in the chamber 11 is at a higher pressure than the “forming” gas in the chamber 13. The annealing process is thus carried out from the rearside of the wafer 5 only, stopping at a nitride barrier layer inside the water. The process is typically performed at a temperature in the range 300 to 450° C. The lamp 1 constitutes a heater for heating the wafer 5. However, this is not the only way in which the wafer could be heated. For example, the gases entering the chambers 11, 13 could be at a temperature selected to heat the wafer.

FIG. 2 is a cross-sectional TEM (transmission electron microscopy) view of a part of a known FeRAM structure which can be processed in the apparatus of FIG. 1. It has a rear side shown generally as 21 and a front side shown as 22. It includes ferrocapacitors 23, including respective ferroelectric elements 24, and electrical contacts 25 which contact upper electrodes (not labelled) above the ferroelectric elements 24. Typically, there are no further layers of ferrocapactitors above the ferrocapacitors 23, only metallization and passivation layers. The lowest level of the structure is CMOS devices 26, just over the silicon substrate 27. Directly above the CMOS devices 26, the structure is mainly BPSG (Boron-Phosphorus-Silicon glass), including barrier layers, as in known devices, such as a nitride layer 28 which acts as a barrier layer between the BPSG and SiO₂ above the barrier layer 28.

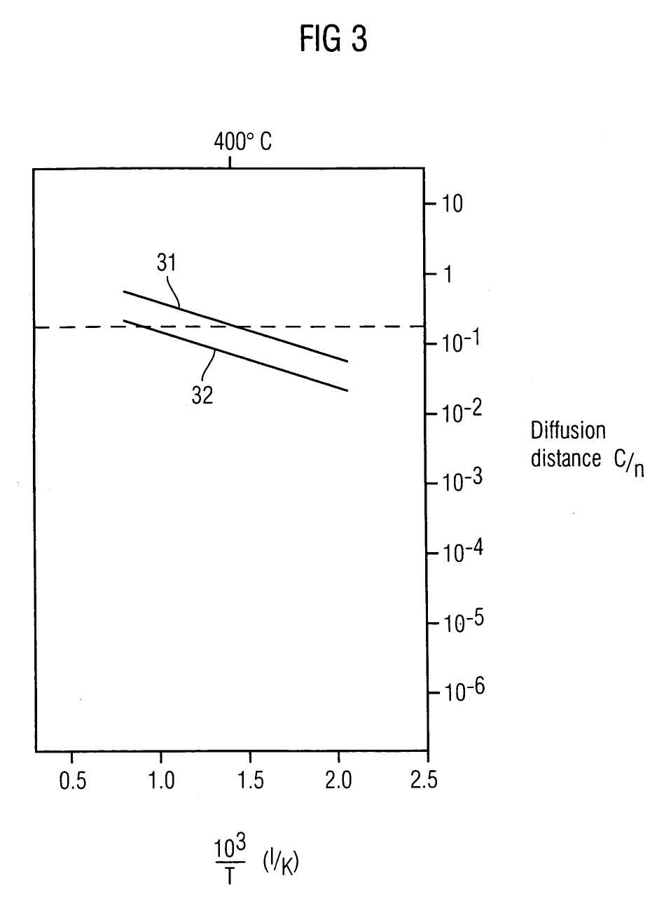

Referring to FIG. 3, the diffusion distance of hydrogen molecules in centimetres in one hour at different temperatures through Si is shown as line 31, and through SiO₂ as line 32. For example, at a temperature of 400 k, the diffusion distance through Si is about 5 cm. The vertical scale is logarithmic in distance and the horizontal scale is linear in the reciprocal of temperature. Clearly, the diffusion rate is higher through the Si. This means that the hydrogen in the chamber 13 will diffuse relatively rapidly to the devices 26, but will diffuse to a much lesser extent to the upper parts of the structure shown in FIG. 2, and thus is unlikely to cause damage to the ferroelectric elements 24. The diffusion of the hydrogen will be also resisted by the nitride layer 28 which acts as a diffusion blocker for a typical annealing gas.

Although only a few embodiments of the invention have been illustrated in detail, the invention is not limited in this respect and many variations are possible within the scope of the invention as will be clear to an expert in this field. For example, the invention is not limited to FeRAM device fabrication, but may be used in any integrated circuit production method including a gas annealing step.

1. An apparatus for performing an annealing step on a wafer comprising integrated circuit elements, the apparatus comprising:
a first chamber,
a second chamber,
a support for holding the wafer at a location in which a first surface of the wafer is exposed in the first chamber and a second surface of the wafer is exposed in the second chamber,
a heater for heating the wafer in the location,
first and second gas delivery systems for respectively delivering first and second different gases into the first and second chambers, and
pressure regulating devices for regulating the pressure in the first chamber to be different from the pressure in the second chamber.

2. An apparatus according to claim 1 further including a partition at least partly dividing the first chamber from the second chamber and including an opening including said wafer location.

3. An integrated circuit fabrication method including a step of maintaining a wafer including one or more integrated circuit elements at a temperature of at least 300° C., a first surface of the wafer being exposed to a first gas and a second surface of the wafer being exposed to a second gas.

4. A method according to claim 3 in which the first gas is inert and the second gas is active in a thermal treatment applied to at least one component of the wafer.

5. A method according to claim 4 in which the first gas is at a higher pressure than the second gas.

6. A method according to claim 4 in which the integrated circuit comprises at least one barrier layer for blocking the diffusion through the wafer of molecules of the second gas.

7. A method according to claim 6 in which the barrier layer comprises a nitride layer.

8. A method according to claim 4 in which the wafer is an FeRAM device having ferrocapacitor elements and CMOS elements, the CMOS elements being closer to the second surface of the device than the ferrocapacitor elements and separated from the FeRAM device by a diffusion blocker layer, and the second gas being active in a CMOS device fabrication step.

9. A method according to claim 8 in which the second surface of the wafer is a surface of the substrate and the first surface is the surface of a structure deposited on the substrate.

10. A method according to claim 8 in which the ferrocapactor elements are in an SiO₂ matrix.

11. An integrated circuit produced by a method according to claim 3.
